(19) United States
(12) Patent Application Publication
(10) Pub. No.: US 2003/0122453 A1
(43) Pub. Date: Jul. 3, 2003

(54) Elastic wave element and method for fabricating the same

(76) Inventors: Akira Yamada, Tokyo (JP); Chisako Maeda, Tokyo (JP); Shoji Miyashita, Tokyo (JP); Koichiro Misu, Tokyo (JP); Tsutomu Nagatsuka, Tokyo (JP); Atsushi Sakai, Tokyo (JP); Kenji Yoshida, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 10/296,639

(22) PCT Filed: Dec. 11, 2001
(86) PCT No.: PCT/JP01/10828

(30) Foreign Application Priority Data
Mar. 30, 2001 PCT/JP01/02714

(51) Int. Cl. H01L 41/08

(52) U.S. Cl. 310/363

(57) ABSTRACT

An elastic wave element including a piezoelectric member, at least one electrode which is formed on the piezoelectric member, a corrosion-resistant layer which is formed on a surface of the electrode, a hydrophilic film which is formed on the corrosion-resistant layer and a dielectric film which is formed on the hydrophilic film, in which the corrosion-resistant layer is made is made of a compound of a material of the electrode and the hydrophilic film is made of a material having higher hydrophilic nature than that of the dielectric film such that the corrosion-resistant layer, the hydrophilic film and the dielectric film prevent erosion of the electrode by atmospheric water content.

### TECHNICAL FIELD

The present invention generally relates to an elastic wave applicable, as oscillators, filters, etc., to a wide range of industrial fields such as fields of communications, images, etc. and more particularly, to an elastic wave element capable of exhibiting excellent environmental resistance and high reliability without incurring deterioration of electrical characteristics, and a method of manufacturing the elastic wave element.

### BACKGROUND ART

Elements utilizing an elastic wave are quite widely used for communication appliances such as cellular phones and other electrical appliances. An element utilizing an ultrasonic wave called a “surface acoustic wave” (SAW) propagating on a surface of single-crystal piezoelectric or a piezoelectric thin film can be recited as a typical example of such elements.

One example of conventional SAW elements is shown in FIG. 10. In this conventional SAW element, input and output electrodes in each of which a pair of electrodes are combined with each other like teeth of opposed combs are formed on a surface of a piezoelectric crystal 1. By applying an input signal to a pair of electrodes 2, the piezoelectric crystal 1 is distorted so as to generate a surface wave. On the piezoelectric crystal 1, this surface wave is propagated to another pair of comb-shaped electrodes 3 and is fetched as an output signal by an effect contrary to that of the electrodes 2. In order to upgrade performance of the conventional SAW element, efficient excitation of the ultrasonic wave is quite vital.

To this end, the electrodes should have excellent electrical conductivity and be light in weight for efficient excitation of the ultrasonic wave, a material which mainly contains aluminum is used for the electrodes. The material which mainly contains aluminum is favorable electrically and in terms of weight but has a greatest disadvantage that it is likely to undergo corrosive deterioration. On the other hand, at present, it is difficult to find a material which can replace aluminum.

Meanwhile, the comb-shaped electrodes are formed at a submicron accuracy in high-frequency applications and therefore, are readily short-circuited or damaged even by adhesion of dust or the like. Hence, in order to prevent deterioration of the electrodes, the SAW element is sealed in a hermetic package together with inert gas. However, this hermetic package is quite expensive as compared with the SAW element and the manufacturing process becomes complicated.

In order to solve these problems, a method is known in which organic matter or a thin film of organic matter for coating the electrodes is formed on the electrodes so as to prevent dust, water content or corrosive material from coming into contact with the electrodes. For example, Japanese Patent Laid-Open Publication No. 8-97671 (1996) discloses a laminated structure in which an outer protective film of silicon nitride is formed on electrodes of a SAW device via an inner protective film of silicon oxide. By this structure, distortion produced from a substrate to the outer protective film due to a difference in coefficient of linear expansion therebetween is mitigated and thus, production of cracks on the outer protective film is prevented. The above publication teaches that the SAW device which prevents short circuit between the electrodes and their contamination by metallic chips as well as deterioration of the electrodes due to moisture is materialized by the above mentioned structure.

In an element utilizing an elastic wave, presence of an unnecessary mass at an oscillatory portion results in deterioration of the characteristics. Therefore, in case a thin film is coated on electrodes, it is desirable for preventing deterioration of the characteristics that density of the thin film is small and the thin film is as thin as possible. Meanwhile, elastic loss of the thin film itself should be small. On the other hand, in many cases, the thin film has defects. If the thin film is extremely thin, the thin film has many defects and water content or the like penetrates from the defects. Thus, the environmental resistance such as humidity resistance cannot be improved sufficiently. Therefore, it is necessary to satisfy the above mentioned two contradictory requirements.

Meanwhile, control of the film thickness is quite vital. If control of the film thickness is insufficient in a filter element, deterioration of the characteristics, for example, increase of loss of the pass band and deterioration of shape of the pass band or variations of the characteristics, for example, variations of the center frequency are incurred, so that it is quite difficult to manufacture the product stably. In conventional elements, a step of forming the thin film is performed a plurality of times. Positions of defects of the firstly formed thin film are apt to be different from those of the secondly formed thin film. Therefore, in case each of the first and second thin films has a sufficiently large film thickness, it is considered that more stable environmental resistance can be obtained. However, since the step of forming the thin film, which requires sophisticated film thickness control, should be performed two times, variations of characteristics of the elements may increase.

Meanwhile, if, a final thickness of a protective film of a two-layer construction is made equal to that of a protective film of a single layer, a thickness of each layer of the film of the two-layer construction naturally becomes extremely smaller than that of the film of the single layer, so that ratio of presence of defects in the film of the two-layer construction may become larger than that of the film of the single layer. Therefore, final protective performance of the film of the two-layer construction does not necessarily become more excellent than that of the film of the single layer apparently.

In the foregoing, a SAW element used widely in industrial fields has been described as a typical example of an elastic wave element but an element utilizing a bulk ultrasonic wave is also considered to have similar inconveniences.

### DISCLOSURE OF INVENTION

The present invention has for its object to provide, with a view to eliminating the above mentioned drawbacks of prior art, an elastic wave element having excellent humidity resistance and high reliability as well as its manufacturing method.

In order to accomplish this object of the present invention, an elastic wave element according to the present invention includes a piezoelectric member and at least one electrode formed on the piezoelectric member. Meanwhile, a corrosion-resistant layer is formed on a surface of the electrode and a dielectric film is formed on the corrosion-resistant layer such that the corrosion-resistant layer is made of a compound of a material of the electrode.

In order to prevent deterioration of characteristics of the element, the thin film formed on the electrode should be as thin as possible and should be made of a light material for reducing additional weight. Meanwhile, penetration of corrosive substance such as water content from defects which will be necessarily produced in the thin film should be prevented as much as possible. Furthermore, since variations of the film thickness and load mass lead to variations of characteristics of the element, the manufacturing process including the film formation step is desirably simple and easy to control. By studying various materials, arrangements and manufacturing processes in view of these factors, the present inventors have found that the following arrangements, materials and manufacturing methods are quite effective for obtaining desired performance.

In an elastic wave: element which includes a piezoelectric member, an electrode and a dielectric member as its main constituent elements, employment of an arrangement in which a surface of the electrode formed on the piezoelectric member is formed into a compound prior to formation of the dielectric member and then, the dielectric film is formed is effective for accomplishing the above object. The compound itself on the surface of the electrode should be a chemically stable material having excellent environmental resistance. The same also applies to the dielectric film. By performing a compounding operation on the surface of the electrode, not only environmental resistance of the electrode itself is upgraded but defects or corrosive active sites of the electrode are restrained through their preferential reaction. In addition, by adding the dielectric film having a proper thickness, resistance against erosive substance penetrating through the defects in the dielectric film is obtained and thus, erosion can be restricted to a slight level.

In this arrangement, material of the effective piezoelectric member is not limited specifically. Material of the electrode is not limited fundamentally. However, actually in view of the electrode usable in the elastic wave element, metals containing mainly aluminum, copper, silver and palladium or an arrangement in which materials including, these metals are laminated on each other or formed as mixed crystal can be effectively applied to the electrode.

Materials of the dielectric film should be chemically stable and light in weight. It is preferable that the formation step conveniently does not require high temperatures leading to deterioration of the element and the materials have few detects leading to penetration of the corrosive substance. As preferable materials of the dielectric film, which satisfy these requirements, silicon oxide, silicon nitride and oxynitriding silicon which have so far been widely used in semiconductor field are effective and aluminum oxide, aluminum nitride, zirconium oxide and diamond which have excellent chemical stability and high mechanical strength are also effective.

Materials effective for the compound on the surface of the electrode should be more stable chemically than the electrode and should not be affected in the step for forming the dielectric film after formation of the compound. The materials of the compound may include any element for forming a chemically stable compound with the material of the electrode and therefore, are not specifically restricted to an oxide, a nitride, a carbide, a boride, a silicide, an intermetallic compound, etc. However, if easiness of the manufacture is taken into consideration, an oxide or a nitride of a metal forming the electrode is effective for the compound.

Especially, in case the electrode consists mainly of aluminum, aluminum oxide or aluminum nitride is effective as the material of the compound. The corrosion-resistant layer (compound layer) functions for preferential reaction of either crystalline defects of the electrode or corrosive active sites due to mixing of impurities, etc. and inactivation based on compounding and therefore, is not required to be formed thickly. The thinner corrosion-resistant layer (compound layer) is also desirable for restraining variations of characteristics of the element caused by the manufacturing process.

As an especially effective combination of materials, an arrangement can be recited in which the electrode consists mainly of aluminum, the dielectric film held in contact with the corrosion-resistant layer (compound layer) consists mainly of silicon oxide and the corrosion-resistant layer (compound layer) consists mainly of aluminum oxide. The protective arrangement of the corrosion-resistant layer (compound layer) and the dielectric film is especially excellent in chemical stability and is also preferable in close contact and convenience of the manufacturing steps.

In another effective arrangement, the electrode consists mainly of aluminum, the dielectric film held in contact with the corrosion-resistant layer (compound layer) consists mainly of silicon nitride and the corrosion-resistant layer (compound layer) consists mainly of aluminum oxide. This arrangement has advantages similar to those of the above arrangement but has differences that in comparison with the above arrangement, environmental resistance of the dielectric film is excellent but process control becomes slightly complicated due to large stress in the dielectric film. A decision as to which one of the above two arrangements is proper is made based on environment for using the product.

In still another effective arrangement, the electrode consists mainly of aluminum and both the dielectric film held in contact with the corrosion-resistant layer (compound layer) and the corrosion-resistant layer (compound layer) consist mainly of aluminum oxide. Since the dielectric film and the corrosion-resistant layer (compound layer) are made of the same material, this arrangement is advantageous in that such improper phenomena as separation of the dielectric film, etc. are least likely to happen, thereby resulting in high reliability of the element.

Hereinafter, manufacturing methods of the elastic wave element of the above described arrangements are described. For forming the dielectric film, DC sputtering, AC sputtering, sputtering utilizing opposed targets and chemical vapor deposition (CVD) utilizing such auxiliaries as plasma are applicable. However, sputtering and CVD which utilize high-efficiency plasma, for example, microwave plasma are effective for forming the dielectric film in which the number of defects should be small.

For forming the corrosion-resistant layer (compound layer), a technique which is capable of forming on the surface of the electrode a thin and dense layer having a high compounding ratio is desirable. In order to form such a corrosion-resistant layer (compound layer), a method is effective in which an element of the corrosion-resistant layer (compound layer) other than those forming the electrode is supplied from liquid or gaseous phase including the element such that a reaction of the element is caused on the surface of the electrode under specific conditions. In order to form the high-quality corrosion-resistant layer (compound layer) by supplying the reactive element, simultaneous irradiation of plasma is effective and especially, microwave plasma having excellent reactivity is effective. Meanwhile, in case the electrode consists mainly of aluminum, a boehmite treatment in which the electrode is exposed to high-temperature steam for a short period and a chemical conversion treatment utilizing alkali solution or steam are also effective.

Furthermore, in the elastic wave element which includes, as its most fundamental essential constituent elements, the piezoelectric member and not less than one electrode for driving the piezoelectric member, which is formed on the piezoelectric member, an arrangement which includes an intermediate protective film formed on the electrode and the dielectric film formed on the intermediate protective film such that the intermediate protective film has higher hydrophilic nature than that of the dielectric film is effective for solving the above problems. In this arrangement, the respective protective films have the following effects. Moisture resistance in the above arrangement mainly relies on the dielectric film. In this element, thickness of the protective film cannot be made large as described above. In view of characteristics of the element, it is actually considered that the element should exhibit moisture-resistant performance when thickness of the protective film is not more than 100 nm. However, in the protective film having a thickness of not more than 100 nm, it is quite difficult to eliminate defects and obtain complete moisture-resistant performance. A minute amount of water content or the like unavoidably penetrates into the element via defects present in the protective film. In this arrangement, the minute amount of the water content which has penetrated into the element is caught by the intermediate protective film disposed between the dielectric film and made of a material having hydrophilic nature. As a result, since erosion, especially, local erosion of the electrode by the penetrating water content can be prevented, performance of the element can be upgraded.

In the above arrangement, water content to be handled by the intermediate protective film is the minute amount of the water content which has penetrated into the element and material of the intermediate protective film has hydrophilic nature such that the water content is captured by the material itself of the intermediate protective film. Therefore, since the intermediate protective film can catch the water content during pass of the water content therethrough, presence of some defects in the intermediate protective film does not pose a problem. Meanwhile, since the intermediate protective film may handle a minute amount of water content, the intermediate protective film having a smaller thickness than that of the dielectric film acting as an outer protective film can manifest its effects. Since thickness of the intermediate protective film may be quite small as described above, influence exerted by variations of the film thickness in the manufacturing process is minimized. The intermediate protective film effectively has a thickness of 5 to 50 nm in terms of characteristics of the element, humidity resistance characteristics and easiness of the manufacturing process but preferably, has a thickness of 5 to 20 nm especially.

In addition to these protective films, an arrangement is combined effectively in which the corrosion-resistant layer (compound layer) obtained by compounding the surface of the electrode is provided such that especially, active sites apt to be turned into corrosive sites are preferentially stabilized. The compound itself on the surface of the electrode should have environmental resistance and be chemically stable. The same also applies to the dielectric film. By performing the compounding operation on the surface of the electrode, environmental resistance of the electrode itself is improved and defects acting as a starting-point of erosion in the electrode tare stabilized by their preferential reaction, so that further erosion of the electrode is restrained. Moreover, by adding the dielectric film and the intermediate protective film each having a proper thickness, resistance against substance penetrating via defects in the dielectric film is obtained and thus, erosion can be restrained to a slight degree.

A material which has affinity for water content and can be formed into a thin film is effective for the intermediate protective film. As materials which can be manufactured as the intermediate protective film, silicon oxide including many defects, for example, a material including many Si—O bonds is effective. Meanwhile, a material which includes a large quantity of boron, phosphorus or alkali metal in silicon oxide is likely to absorb water content in comparison with a single composition of SiO₂ and therefore, is also effective. In order to manufacture the intermediate protective film of these compositions, a technique in which liquid such as sol or gel of alcoxide as a raw material is coated by spin coating and then, formed into a thin film by heating is convenient and is preferable thanks to comparative easiness for obtaining the thin film. Especially, in a composition in which a content of silicon oxide is large, etc., silicon dioxide is produced by a high-temperature heat treatment but hydrophilic; nature can be changed by changing heating conditions after coating in case the hydrophilic nature drops greatly. If a heating temperature is low, it is difficult to produce sufficiently strong bonds between silicon and oxygen and hydrophilic nature is readily generated. In a composition which contains an additional matter, etc. and has high hydrophilic nature essentially, the intermediate protective film may be formed by general CVD or sputtering. Since the intermediate protective film does not intercepts water content by its thickness, the intermediate protective film is not required to be made thick. In many cases, since density of the intermediate protective film is low, influence exerted on characteristics of the element by the intermediate protective film is slight, so that control of thickness of the intermediate protective film is not required to be performed so strictly as the dielectric film.

In case the dielectric film is made of a material such as hydrophilic silicon oxide, hydrophilic nature of the dielectric film may be impaired when the dielectric film is processed at high temperatures, so that the dielectric film is effectively formed at not more than about 300° C., preferably in the vicinity of 100° C. Therefore, in order to form the dielectric film, techniques such as microwave CVD, plasma CVD, RF sputtering and microwave sputtering are effective.

### BRIEF DESCRIPTION OF DRAWINGS

FIG. 1 is a schematic top plan view of a SAW element according to first and sixth embodiments of the present invention.

FIG. 2 is a sectional view of electrodes along the line II-II in FIG 1.

FIG. 3 is a sectional view of electrodes of a SAW element according to a second embodiment of the present invention.

FIG. 4 is a schematic top plan view of a SAW element according to a third embodiment of the present invention.

FIG. 5 is a sectional view taken along the line V-V in FIG. 4.

FIG. 6 is a sectional view of electrodes of a SAW element according to a fourth embodiment of the present invention.

FIG. 7 is a sectional view of electrodes of a SAW element according to a fifth embodiment of the present invention.

FIG. 8 is a schematic top plan view of a SAW element according to seventh to eleventh embodiments of the present invention.

FIG. 9 is a sectional view of electrodes along the line IX-IX in FIG. 8.

FIG. 10 is a schematic top plan view of a prior art SAW element.

### BEST MODE FOR CARRYING OUT THE INVENTION

Hereinafter, embodiments of the present invention are described with reference to the drawings.

(First Embodiment)

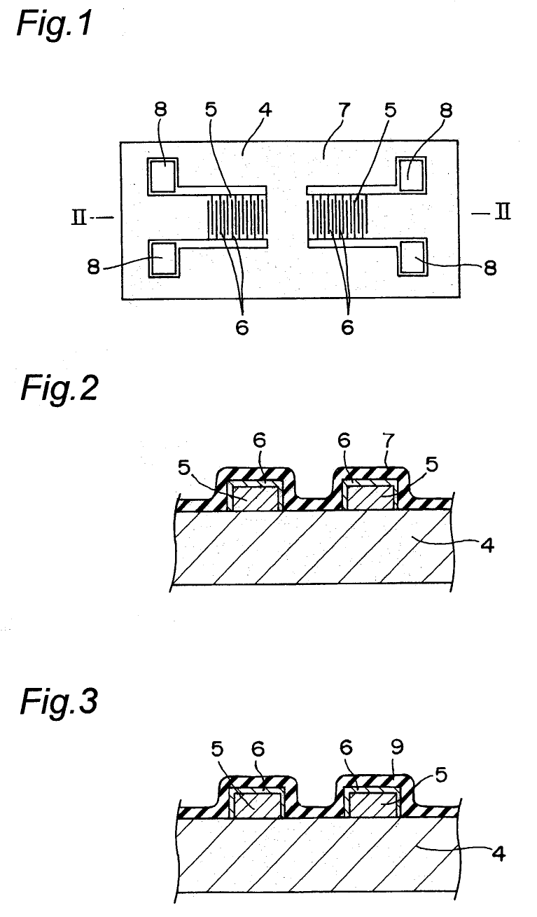

An upper face of electrodes of a surface acoustic wave (SAW) element which has been manufactured is shown schematically in FIG. 1. Meanwhile, in FIG. 2, a portion of the electrodes is shown on an enlarged scale and other portions of the electrodes are` abbreviated. All the electrodes have a similar construction. The manufacturing steps are described below. An aluminum thin film is formed on a piezoelectric substrate 4 of single-crystal lithium tantalate in atmosphere of 100% argon gas by DC sputtering. By performing chemical etching of the formed aluminum film by using a resist as a mask, a comb-shaped electrode 5 is formed. By irradiating RF plasma to the substrate 4 for 10 min. at a pressure of 10 mTorr in a mixed gas containing argon and 50% oxygen, a surface of the electrode 5 is oxidized such that a corrosion-resistant layer 6 made of aluminum oxide is formed as a compound layer.

Subsequently, by using tetraethyl orthosilicate (TEOS) as a silicon source in plasma chemical vapor deposition (CVD) under the conditions that a ratio of a flow rate of TEOS to that of oxygen is set to 1:50, a pressure is set to 0.5 Torr and a temperature of the substrate 4 is set to 300° C., a dielectric film 7 made of silicon oxide is formed. The formed dielectric film 7 has thicknesses of 5 nm, 10 nm, 20 nm, 40 nm, 60 nm, 100 nm and 200 nm. Then, the dielectric film 7 on pads is removed by reactive dry etching so as to form openings 8 and thus, the element is obtained. After the obtained element has been allowed to stand at 85° C. and a relative humidity of 85% for 500 hr., change of its insertion loss is measured. The measurement results are shown in Table 1 below.

TABLE 1

| Thickness of | | Increase | Increase |
|---|---|---|---|
| corrosion- | Thickness of | amount 1 of | amount 2 of |
| resistant layer | dielectric film | insertion loss | insertion loss |
| (nm) | (nm) | (dB) | (dB) |
| — | 0 | >+1.0 | — |
| 4 | 5 | +0.3 | <+0.1 |
| 3 | 10 | <+0.2 | +0.1 |
| 3 | 20 | <+0.2 | +0.2 |
| 5 | 40 | <+0.2 | +0.2 |
| 6 | 60 | <+0.1 | +0.3 |
| 3 | 100 | <+0.1 | +0.5 |
| 6 | 200 | <+0.1 | +2.1 |

In Table 1, the thickness of the corrosion-resistant layer 6 represents a measurement value of one element and is expressed by one significant figure due to its low measurement accuracy. Meanwhile, in Table 1, the thickness of the dielectric film 7 represents a value estimated from a film formation speed and a film formation period and an actual thickness of the dielectric film 7 falls within ±5% of the estimated value. Furthermore, in Table 1, increase amount 1 of insertion loss and increase amount 2 of insertion loss represent results obtained by averaging measurements of five elements. The increase amount 1 of insertion loss denotes a change amount of an insertion loss after the above humidity resistance test relative to that prior to the humidity resistance test. Meanwhile, the increase amount 2 of insertion loss denotes a difference of the element manufactured by the first embodiment and that of an element of the same type as the element of the first embodiment, which does not have the corrosion-resistant layer 6 and the dielectric film 7 and is referred to as a “conventional element”, hereinafter. The increase amount 2 of insertion loss indicates to what degree the insertion loss is deteriorated by presence of the corrosion-resistant layer 6 and the dielectric film 7. In Table 1, a sample in which the thickness of the dielectric film 7 is 0 nm represents a comparative example.

Change amount of insertion loss after the humidity resistance test should be desirably small and increase of insertion loss due to formation of the corrosion-resistant layer 6 and the dielectric layer 7 also should be desirably small. In both of the cases, the increase amounts 1 and 2 of insertion loss, which are substantially not more than 0.5 dB, will be acceptable. Upon review of Table 1 in terms of these criteria, an arrangement in which the corrosion-resistant layer 6 and the dielectric film 7 are added is effective for improving humidity resistance and the corrosion-resistant layer 6 having a thickness of not more than 20 nm and the dielectric film 7 having a thickness of not less than 5 nm are effective. However, since the increase amount 2 of insertion loss, which is caused by addition of the corrosion-resistant layer 6 and the dielectric film 7, is restricted to not more than 0.5 dB when the corrosion-resistant layer 6 has a thickness of not more than 20 nm and the dielectric film 7 has a thickness of not more than 100 nm, satisfactory results are apparently obtained when the corrosion-resistant layer 6 has a thickness of not more than 20 nm and the dielectric film 7 has a thickness of 5 to 100 nm.

Meanwhile, in contrast with an insulating layer for insulating the electrode 5, the corrosion-resistant layer 6 is not required to be provided on a whole surface of the electrode 5 thickly in a layered state but may be provided quite thinly only on a surface portion of the electrode 5, whose corrosion resistance is weak.

(Second Embodiment)

By the following steps, a SAW element similar to that of the first embodiment is manufactured. FIG. 3 shows its electrodes on an enlarged scale. Manufacturing steps are described below. Steps up to formation of the comb-shaped electrode 5 are performed in the same manner as the first embodiment. By irradiating RF plasma to the substrate 4 at a pressure of 10 mTorr in a mixed gas containing argon and 50% oxygen, a surface of the electrodes 5 is oxidized such that a corrosion-resistant layer 6 made of aluminum oxide is formed as a compound layer.

Subsequently, by, using silane gas as a silicon source in plasma CVD under the conditions that a ratio of a flow rate of silane to that of ammonia is set to 1:1, a pressure is set to 0.7 Torr and a temperature of the substrate 4 is set to 300° C., a dielectric film 9 made of silicon nitride is formed. The formed dielectric film 9 has a thickness of 20 nm. Then, the dielectric film 9 on pads is removed by reactive dry etching so as to form the openings 8 and thus, the element is obtained. After the obtained element has been allowed to stand at 85° C. and a relative humidity of 85% for 500 hr., change of its insertion loss is measured. In the obtained element, change amount of the insertion loss relative to a conventional element is +0.1 dB and increase of the insertion loss after the humidity resistance test is not more than +0.2 dB, which are satisfactory results apparently.

(Third Embodiment)

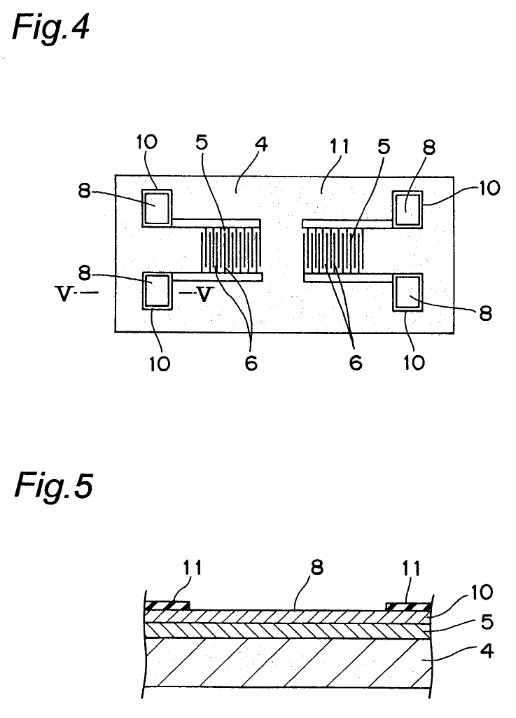

A SAW element shown in FIGS. 4 and 5 is manufactured by the following steps. The electrode 5 is similar to that of FIG. 2 except for its material. The manufacturing steps are described below. After an aluminum thin film has been formed, a gold film 10 having a thickness of 200 nm and acting as an etching stop film at the time of etching of a dielectric film is subjected to deposition and patterning by applying a lift-off method to pad portions of the substrate 4. Then, the comb-shaped electrode 5 is formed in the same manner as the first embodiment. Then, by irradiating RF plasma to the substrate 4 at a pressure of 10 mTorr in a mixed gas containing argon and 50% oxygen, a surface of the electrode 5 is oxidized such that a corrosion-resistant layer 6 made of aluminum, oxide is formed as a compound layer.

Subsequently, by using alcoxide of aluminum as a raw material source in plasma CVD under the conditions that a ratio of a flow rate of the aluminum source gas to that of oxygen is set to 1:10, a pressure is set to 0.5 Torr and a temperature of the substrate 4 is set to 300° C., a dielectric film 11 made of aluminum oxide is formed. The formed dielectric film 11 has a thickness of 30 nm. Thereafter, by removing the dielectric film 11 on the pads by dry etching, the openings 8 are formed and thus, the element is obtained. After the obtained element has been allowed to stand at 85° C. and a relative humidity of 85% for 500 hr., change of its insertion loss is measured. In the obtained element, change, amount of the insertion loss relative to a conventional element is +0.3 dB and increase of the insertion loss after the humidity resistance test is +0.3.dB, which are satisfactory results apparently.

(Fourth Embodiment)

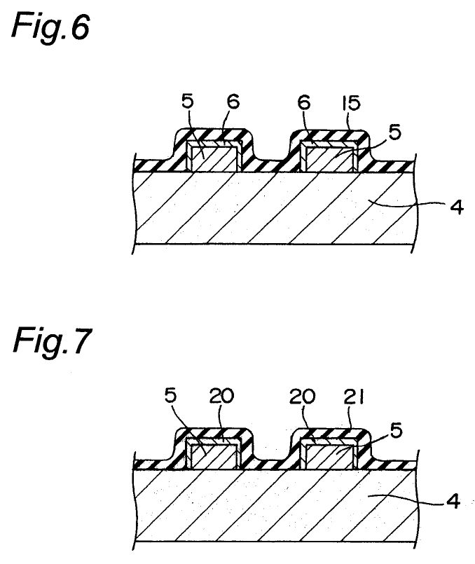

A SAW element shown in FIG. 6 is manufactured by the following steps. The electrode 5 is similar to that of FIG. 2 except for its material. The manufacturing steps are described below. Steps up to formation of the comb-shaped electrode 5 are performed in the same manner as the third embodiment. By irradiating RF plasma to the substrate 4 at a pressure of 10 mTorr in a mixed gas containing argon and 50% oxygen, a surface of the electrode 5 is oxidized such that a corrosion-resistant layer 6 made of aluminum oxide is formed as a compound layer.

Subsequently, by using sintered zirconium oxide as a target in RF magnetron sputtering under the conditions that a ratio of a flow rate of argon to that of oxygen is set to 80:20, a pressure is set to 10 mTorr and a temperature of the substrate 4 is set to 100° C., a dielectric film 15 made of zirconium oxide is formed. The formed dielectric film 15 has a thickness of 30 nm. Thereafter, by removing the dielectric film 15 on the pads by dry etching, the openings 8 are formed and thus, the element is obtained. After the obtained element has been allowed to stand at 85° C. and a relative humidity of 85% for 500 hr., change of its insertion loss is measured. In the obtained element, change amount of the insertion loss relative to a conventional element is +0.2 dB and increase of the insertion loss after the humidity resistance test is +0.3 dB, which are satisfactory results apparently.

(Fifth Embodiment)

A SAW element shown in FIG. 7 is manufactured by the following steps. The electrode 5 is similar to that of FIG. 2 except for its material. The manufacturing steps are described below. Steps up to formation of the comb-shaped electrode 5 are performed in the same manner as the fourth embodiment. By irradiating RF plasma to the substrate 4 at a pressure of 10 mTorr in a gas containing 100% nitrogen, a surface of the electrode 5 is nitrided such that a corrosion-resistant layer 20 made of aluminum nitride is formed as a compound layer.

Subsequently, by using aluminum as a target in RF magnetron sputtering under the conditions that a ratio of a flow rate of argon to that of nitrogen is set to 50:50, a pressure is set to 10 mTorr and a temperature of the substrate 4 is set to 300° C., a dielectric film 21 made of aluminum nitride is formed. The formed dielectric film 21 has a thickness of 30 nm. Thereafter, by removing the dielectric film 21 on the pads by dry etching, the openings 8 are formed and thus, the element is obtained. After the obtained element has been allowed to stand at 85° C. and a relative humidity of 85% for 500 hr., change. of its insertion loss is measured. In the obtained element, change amount of the insertion loss relative to a conventional element is +0.3 dB and increase of the insertion loss after the humidity resistance test is +0.3 dB, which are satisfactory results apparently.

(Sixth Embodiment)

A SAW element similar to that shown in FIGS. 1 and 2 is manufactured by the following steps. The electrode 5 is similar to that of FIG. 2 except for its material. The manufacturing steps are described below. Steps up to formation of the comb-shaped electrode 5 are performed in the same manner as the first embodiment. By drying the substrate 4 after its exposition to steam of 120° C. for 30 sec., a surface of the electrode 5 is oxidized such that the corrosion-resistant layer 6 made of aluminum oxide is formed as a compound layer. Subsequently, by using TEOS as a silicon source in plasma CVD under the conditions that a ratio of a flow rate of TEOS to that of oxygen is set to 1:50, a pressure is set to 0.5 Torr and a temperature of the substrate 4 is set to 300° C., the dielectric film 7 made of silicon oxide is formed.

Then, the dielectric film 7 on pads is removed by reactive dry etching so as to form the openings 8 and thus, the element is obtained. The formed dielectric film 7 has a thickness of 20 nm. After the obtained element has been allowed to stand at 85° C. and a relative humidity of 85% for 500 hr., change of its insertion loss is measured. In the obtained element, change amount of the insertion loss relative to a conventional element is +0.5 dB and increase of the insertion loss after the humidity resistance test is +0.3 dB, which are satisfactory results apparently.

(Seventh Embodiment)

An aluminum thin film having a thickness of 200 nm is formed as the electrode 5 on a 3″-diameter dielectric substrate 4 of single-crystal lithium tantalate in atmosphere of 100% argon gas by DC sputtering. By irradiating microwave plasma to the substrate at room temperature at a pressure of 10 mTorr for 10 min. in a mixed gas containing argon and 50% oxygen, electrode processing is performed so as to form a surface of the aluminum metal into a compound such that a corrosion-resistant layer made of aluminum oxide is formed as a compound layer.

By using van der Pauw method which is capable of evaluating at high reproducibility a probe position and electrical conductivity of a sample having a complicated shape, electrical conductivity of the aluminum film is measured. The probe position is set at an outer periphery of a wafer and 1 mA is used as a measuring current. The aluminum film has an electrical conductivity of 4.55 μΩ·cm prior to the plasma processing and an electrical conductivity of 4.60 μΩ·cm after the plasma processing. A cause of an increase of resistance value of the aluminum film is not certain but may be thermal influence of plasma. At any rate, the corrosion-resistant layer does not impart insulating property to the aluminum film.

In case insulating oxide is formed on a surface of a conductor, a coating of the insulating oxide, which has a thickness of about 20 to 30 nm, will exhibit insulating property sufficiently. In order to evaluate thickness of the corrosion-resistant layer, a portion of the substrate, which includes the aluminum film, is processed in a direction of its depth by focused ion beam (FIB) method and a cross section of the aluminum film is observed by a transmission electron microscope. As a result, an affected zone having a thickness of about 5 to 10 nm is observed on a surface of the aluminum film and is considered to be an aluminum oxide layer formed as the corrosion-resistant layer.

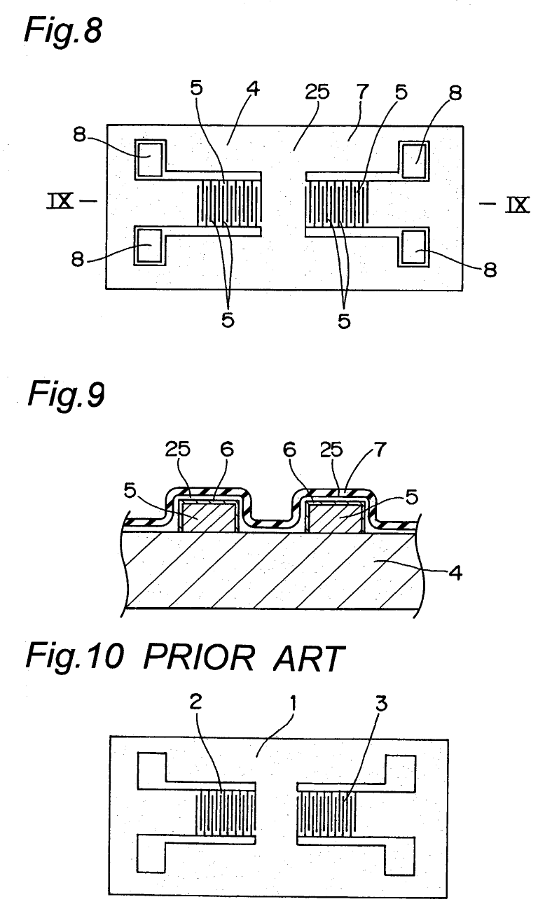

Hereinafter, manufacturing steps of a SAW filter acting as a SAW element are described with reference to FIGS. 8 and 9. Initially, as described above, an aluminum film is formed on a 3″-diameter dielectric substrate 4 of single-crystal lithium tantalate and the comb-shaped electrode 5 is formed by performing dry etching of the aluminum film such that the pass band has a center frequency of 850 MHz. Then, as described above, the corrosion-resistant layer 6 is formed on a surface of the comb-shaped electrode 5.

This substrate is placed in an electron beam deposition apparatus including a substrate inclining mechanism and an autorotation mechanism so as to be subjected to deposition by using quartz tablets as its raw material, so that a hydrophilic film 25 made of silicon oxide and acting as an intermediate protective film is formed. The deposited film thickness is 10 nm. Silicon nitride of the formed hydrophilic film 25 consists mainly of Si—O and is likely to absorb water content in air. After completion of the deposition, silicon oxide is used as a target in RF magnetron sputtering under the conditions that a ratio of a flow rate of argon to that of oxygen is set to 80:20, a pressure is set to 10 mTorr and a temperature of the substrate 4 is set to 100° C., so that the dielectric film 7 made of silicon dioxide and acting as an outer protective film is formed. The formed dielectric film 7 has a thickness of 30 nm. Then, the dielectric film 7 on pads is removed by reactive dry etching so as to form the openings 8 and thus, the element is obtained.

After the obtained element has been allowed to stand at 85° C. and a relative humidity of 85% for 500 hr., change of its insertion loss is measured. In the obtained element, change amount of the insertion loss after the humidity resistance test relative to that prior to the humidity resistance test is +0.5 dB. Meanwhile, a difference in insertion loss between the element of the seventh embodiment and an element which is of a type similar to that of the element of the seventh embodiment but does not have the corrosion-resistant layer 6, the hydrophilic film 25 and the dielectric film 7, namely, the conventional element is +0.1 dB. In this arrangement, since the corrosion-resistant layer 6 has a thickness of 10 nm, the hydrophilic film 25 has a thickness of 10 nm and the dielectric film 7 has a thickness of 20 nm, the element can be obtained in which change of the insertion loss due to addition of these films is small and increase of the insertion loss by the humidity resistance test is small.

(Eighth Embodiment)

An element having an arrangement similar to that of the seventh embodiment is manufactured in a procedure similar to that of the seventh embodiment. In this element, thickness of the corrosion-resistant layer 6 is changed by changing period of microwave processing of the electrode 5. When thickness of the corrosion-resistant layer 6 is evaluated, both a technique of the seventh embodiment and observation results by a scanning electron microscope after exposition of a cross section by FIB method are employed so as to gather data. Meanwhile, when a film thickness of not more than 10 nm is evaluated, processing period is converted from these data by the film thickness. Evaluation results of the manufactured element are shown in Table 2 below.

TABLE 2

| Thickness | | | | |
|---|---|---|---|---|
| of | Thickness | | Increase | Increase |
| corrosion- | of | Thickness | amount 1 of | amount 2 of |
| resistant | hydrophilic | of dielectric | insertion | insertion |
| layer (nm) | film (nm) | film (nm) | loss (dB) | loss (dB) |
| 0 | 0 | 0 | >+1.0 | — |
| 2 | 0 | 20 | <+0.2 | +0.2 |
| 2 | 10 | 75 | <+0.1 | +0.5 |
| 2 | 11 | 81 | <+0.1 | +0.5 |
| 3 | 0 | 30 | <+0.2 | +0.2 |
| 3 | 9 | 10 | +0.2 | +0.2 |
| 3 | 22 | 43 | <+0.1 | +0.3 |
| 3 | 35 | 63 | <+0.1 | +0.5 |
| 5 | 0 | 30 | <+0.2 | +0.3 |
| 5 | 10 | 50 | <+0.1 | +0.4 |
| 5 | 18 | 72 | <+0.1 | +0.5 |
| 7 | 0 | 35 | <+0.2 | +0.2 |
| 7 | 25 | 60 | <+0.1 | +0.5 |
| 10 | 8 | 53 | <+0.1 | +0.3 |
| 11 | 20 | 72 | <+0.1 | +0.5 |
| 11 | 35 | 60 | <+0.1 | +0.5 |
| 20 | 0 | 30 | <+0.2 | +0.4 |
| 20 | 12 | 32 | <+0.2 | +0.5 |
| 27 | 0 | 0 | — | >+1.1 |
| 25 | 12 | 25 | — | >+1.0 |

In Table 2, increase amount 1 of insertion loss, denotes an increase of a minimum insertion loss of the pass band after the humidity resistance test relative to that prior to the humidity resistance test in which the element is held at 85° C. and a relative humidity of 85% for 500 hr., while increase amount 2 of insertion loss denotes a change amount of the insertion loss of the element having the corrosion-resistant layer 6, the hydrophilic film 25 and the dielectric film 7 as shown in FIG. 9, relative to that of the conventional element which does not have the corrosion-resistant layer 6, the hydrophilic film 25 and the dielectric film 7.

In 20 samples in Table 2, samples of the 1st row, the 19th row and the 20th row are comparative examples. It is understood from Table 2 that change of the increase amount 1 of insertion loss in the case of provision of the hydrophilic film 25, relative to thickness of the dielectric film 7 is more gentle than that of a case in which the hydrophilic film 25 is not provided.

(Ninth Embodiment)

An element having an arrangement similar to that of the seventh embodiment is manufactured in the following steps. Steps up to manufacture of the corrosion-resistant layer 6 are performed in the same manner as the seventh embodiment. Then, 50 cc of commercially available antistatic solution for forming an inorganic thin film is dripped on the substrate and is coated on the substrate by spin coating at 300 rpm for 10 sec. and at 3,000 rpm for 30 sec. As the drip solution, the commercially available product to which ethanol is added is further diluted about 10 times. After the substrate on whose surface the solution is coated has been dried at room temperature, the substrate is further dried at 150° C. for 1 hr. As a result, an antistatic film containing silicon oxide as a base and having a thickness of 10 nm is formed on the substrate. This antistatic film lowers electric resistance of the film surface by absorbing water content to the film surface so as to eliminate static electricity and has hydrophilic nature.

By using silicon oxide as a target in RF magnetron sputtering under the conditions that a ratio of a flow rate of argon to that of oxygen is set to 80:20, a pressure is set to 10 mTorr and a temperature of the substrate 4 is set to 100° C., the dielectric film 7 made of silicon dioxide is formed on the antistatic film. The formed dielectric film 7 has a thickness of 20 nm. Then, the dielectric film 7 on pads is removed by reactive dry etching so as to form the openings 8 and thus, the element is obtained. The obtained element has the same arrangement as that shown in FIGS. 8 and 9. After the obtained element has been allowed to stand at 85° C. and a relative humidity of 85% for 500 hr., change of its insertion loss is measured. A change amount of the insertion loss of the obtained element relative to the conventional element is +0.1 dB and an increase of the insertion loss after the humidity resistance test is not more than +0.1 dB, which are satisfactory results.

(Tenth Embodiment)

An aluminum thin film having a thickness of 200 nm is formed as the electrode 5 on a 3″-diameter dielectric substrate of single-crystal lithium tantalate in atmosphere of 100% argon gas by DC sputtering. By irradiating microwave plasma to the substrate at room temperature at a pressure of 10 mTorr in 100% nitrogen for 10 min., electrode processing is performed so as to form a surface of the aluminum metal into a compound such that a corrosion-resistant layer made of aluminum nitride is formed as a compound layer.

By measuring electrical conductivity of the aluminum film by van der Pauw method, the aluminum film has an electrical conductivity of 4.62 μΩ·cm prior to the plasma processing and an electrical conductivity of 4.63 μΩ·cm after the plasma processing, which exhibit substantially no difference. In order to evaluate thickness of the corrosion-resistant layer, a portion of the substrate, which includes the aluminum film, is processed in a direction of its depth by FIB method and a cross section of the aluminum film is observed by a transmission electron microscope. As a result, an affected zone having a thickness of about 5 nm is observed on a surface of the aluminum film and is considered to be an aluminum nitride layer formed as the corrosion-resistant layer.

An element having an arrangement similar to that of the seventh embodiment is manufactured in the following steps. The corrosion-resistant layer 6 is formed in the above described procedure and the hydrophilic film 25 is formed in the same manner as the seventh embodiment. By using silane gas as a silicon source in plasma CVD under the conditions that a ratio of a flow rate of silane to that of ammonia is set to 1:1, a pressure is set to 0.7 Torr and a temperature of the substrate 4 is set to 275° C., the dielectric film 7 made of silicon nitride and having a thickness of 30 nm is formed. Then, the dielectric film 7 on pads is removed by reactive dry etching so as to form the openings 8 and thus, the element is obtained. The obtained element has the same arrangement as that shown in FIGS. 8 and 9. After the obtained element has been allowed to stand at 85° C. and a relative humidity of 85% for 500 hr., change of its insertion loss is measured. A change amount of the insertion loss of the obtained element relative to the conventional element is +0.1 dB and an increase of the insertion loss after the humidity resistance test is +0.1 dB, which are satisfactory results.

(Eleventh Embodiment)

An element having an arrangement similar to that of the seventh embodiment is manufactured in the following steps. Steps up to manufacture of the corrosion-resistant layer 6 are performed in the same manner as the seventh embodiment. Then, when film formation is performed for 10 sec. by using TEOS as a silicon source and tetraethoxyoxyborate as a boron source in plasma CVD under the conditions that a ratio among a flow rate of TEOS, that of tetraethoxyoxyborate and that of oxygen is set to 1:0.5:50, a pressure is set to 0.5 Torr, a RF power is set to 350 W and a temperature of the substrate 4 is set to 275° C., the hydrophilic film 25 made of silicon oxide including boron as an intermediate protective film and having a thickness of 10 nm is formed.

Furthermore, by using TEOS as a silicon source in plasma CVD under the conditions that a ratio of a flow rate of TEOS to that of oxygen is set to 1:50, a pressure is set to 0.5 Torr, a RF power is set to 350 W and a temperature of the substrate 4 is set to 275° C., the dielectric film 7 made of silicon dioxide as an outer protective film and having a thickness of 20 nm is formed on this structure. Then, the dielectric film 7 on pads is removed by reactive dry etching so as to form the openings 8 and thus, the element is obtained. The obtained element has the same arrangement as that shown in FIGS. 8 and 9.

After the obtained element has been allowed to stand at 85° C. and a relative humidity of 85% for 500 hr., change of its insertion loss is measured. A change amount of the insertion loss of the obtained element after the humidity resistance test relative to that prior to the humidity resistance test is +0.2 dB and a difference of the insertion loss of the obtained element relative to that of the conventional element is +0.3 dB. By this arrangement, the element is obtained in which increase of the insertion loss due to addition of the corrosion-resistant layer 6, the hydrophilic film 25 and the dielectric film 7 is small and increase of the insertion loss by the humidity resistance test is small.

In this embodiment, the hydrophilic film 25 is made of silicon oxide including boron but is not restricted to this material. For example, the hydrophilic film 25 may also be made of silicon oxide including phosphorus.

Moreover, in the seventh to eleventh embodiments, the dielectric film 7 is made of silicon oxide or silicon nitride but is not restricted to these materials. For example, the dielectric film 7 may also be made of aluminum oxide or aluminum nitride.

As is clear from the foregoing description, since the elastic wave element of the present invention includes the piezoelectric member, at least one electrode formed on the piezoelectric member, the corrosion-resistant layer formed on the surface of the electrode, the hydrophilic film formed on the corrosion-resistant layer and the dielectric film formed on the hydrophilic film such that not only the corrosion-resistant layer is made of a compound of a material of the electrode but the hydrophilic film is made of a material having higher hydrophilic nature than that of the dielectric film, humidity resistance and reliability of the elastic wave element are improved greatly and a package can be simplified, so that the elastic wave element can -be made high-performance and inexpensive.

1. An elastic wave element comprising:
a piezoelectric member;
at least one electrode which is formed on the piezoelectric member;
a corrosion-resistant layer which is formed on a surface of the electrode; and
a dielectric film which is formed on the corrosion-resistant layer;
wherein the corrosion-resistant layer is made of a compound of a material of the electrode.

2. An elastic wave element according to claim 1, wherein the corrosion-resistant layer has a thickness of not more than 20 nm.

3. An elastic wave element comprising:
a piezoelectric member;
at least one electrode which is formed on the piezoelectric member;
a corrosion-resistant layer which is formed on a surface of the electrode;
a hydrophilic film which is formed on the corrosion-resistant layer so as to act as an intermediate protective film; and
a dielectric film which is formed on the hydrophilic film so as to act as an outer protective film;
wherein the corrosion-resistant layer is made of a compound of a material of the electrode and the hydrophilic film is made of a material having higher hydrophilic nature than that of the dielectric film.

4. An elastic wave element according to claim 3, wherein the corrosion-resistant layer has a thickness of not more than 20 nm.

5. An elastic wave element according to claim 3, wherein a thickness of the hydrophilic film is not less than 2 nm and not more than 50 nm.

6. An elastic wave element according to claim 3, wherein the material of the hydrophilic film contains silicon oxide having hydrophilic nature.

7. An elastic wave element according to claim 6, wherein the silicon oxide is silicon monoxide.

8. An elastic wave element according to claim 6, wherein the silicon oxide includes boron or phosphorus.

9. An elastic wave element according to claim 3, wherein the dielectric film consists mainly of one of silicon oxide, silicon nitride, aluminum oxide and aluminum nitride.

10. An elastic wave element according to claim 3, wherein the material of the electrode contains aluminum, while a material of the corrosion-resistant layer contains aluminum oxide:
wherein the material of the hydrophilic film contains one of silicon monoxide and silicon oxide including boron or phosphorus, while a material of the dielectric film contains one of silicon oxide, silicon nitride, aluminum oxide and aluminum nitride.

11. A method of manufacturing an elastic wave element, comprising the steps of:
forming a dielectric member;
forming at least one electrode on the dielectric member;
forming on a surface of the electrode a corrosion-resistant layer made of a compound of a- material of the electrode;
forming on the corrosion-resistant layer a hydrophilic film consisting mainly of silicon oxide and acting as an intermediate protective film; and
forming, by sputtering, on the hydrophilic film a dielectric film acting as an outer protective film;
wherein the hydrophilic film is made of a material having higher hydrophilic nature than that of the dielectric film.

12. A method according to claim 11, wherein the hydrophilic film is formed by depositing a material containing silicon monoxide.

13. A method according to claim 11, wherein the hydrophilic film is formed by coating and drying a solution containing a precursor of silicon oxide.
